(19) United States
(12) Patent Application Publication
(10) Pub. No.: US 2012/0154016 A1
(43) Pub. Date: Jun. 21, 2012

(54) SEMICONDUCTOR SWITCH AND METHOD FOR MEASURING SAME

(75) Inventors: Yugo Kunishi, Kanagawa-ken (JP); Toshiki Seshita, Kanagawa-ken (JP)

(73) Assignee: KABUSHIKI KAISHA TOSHIBA, Tokyo (JP)

(21) Appl. No.: 13/234,767

(22) Filed: Sep. 16, 2011

(30) Foreign Application Priority Data
Dec. 20, 2010 (JP) 2010-282989

(51) Int. Cl. H03K 17/56; G01R 27/08

(52) U.S. Cl. 327/407; 324/713

(57) ABSTRACT

According to one embodiment, a semiconductor switch includes a plurality of first switch elements, a second switch element, and a controller. The plurality of first switch elements are connected between a common terminal and each of a plurality of radio frequency terminals including a first terminal and a second terminal. The second switch element is connected between the first terminal and a ground terminal. The controller is configured to output a control signal to turn on or off the plurality of first switch elements and the second switch element and perform a normal operation mode to connect the common terminal to any one of the plurality of radio frequency terminals and a test mode to connect the common terminal to the first terminal, the second terminal, and the ground terminal according to a terminal switching signal.

### CROSS-REFERENCE TO RELATED APPLICATIONS

This application is based upon and claims the benefit of priority from the prior Japanese Patent Application No. 2010-282989, filed on Dec. 20, 2010; the entire contents of which are incorporated herein by reference.

### FIELD

Embodiments described herein relate generally to a semiconductor switch and a method for measuring the same.

### BACKGROUND

Semiconductor switches to open and close a circuit can be used for various electronic devices. In a radio frequency circuit of a mobile phone, for example, a transmitting circuit and a receiving circuit are selectively connected to a common antenna through a semiconductor switch. With an increase in communication standards, the number of ports of the semiconductor switch is also increased. Thus, time reacquired for measuring the radio frequency characteristics of the semiconductor switch is also increased.

### BRIEF DESCRIPTION OF THE DRAWINGS

FIG. 1 is a block diagram illustrating a configuration of a semiconductor switch according to a first embodiment;

FIG. 2 is a circuit diagram illustrating a configuration of a switch section of the semiconductor switch shown in FIG. 1;

FIG. 3 is a truth table showing input-output characteristics of a level shifter of the semiconductor switch;

FIG. 4 is a block diagram illustrating a method for measuring an ON resistance including another configuration of a semiconductor switch;

FIG. 5 is a truth table of first and second circuits of a controller; and

FIG. 6 is a block diagram illustrating another method for measuring an ON resistance of a semiconductor switch.

### DETAILED DESCRIPTION

In general, according to one embodiment, a semiconductor switch includes a plurality of first switch elements, a second switch element, and a controller. The plurality of first switch elements are connected between a common terminal and each of a plurality of radio frequency terminals including a first terminal and a second terminal. The second switch element is connected between the first terminal and a ground terminal. The controller is configured to output a control signal to turn on or off the plurality of first switch elements and the second switch element and perform a normal operation mode to connect the common terminal to any one of the plurality of radio frequency terminals and a test mode to connect the common terminal to the first terminal, the second terminal, and the ground terminal according to a terminal switching signal.

Embodiments will now be described in detail with reference to the drawings. In the specification and drawings, components similar to those described or illustrated in a drawing thereinabove are marked with like reference numerals, and a detailed description is omitted as appropriate.

### First Embodiment

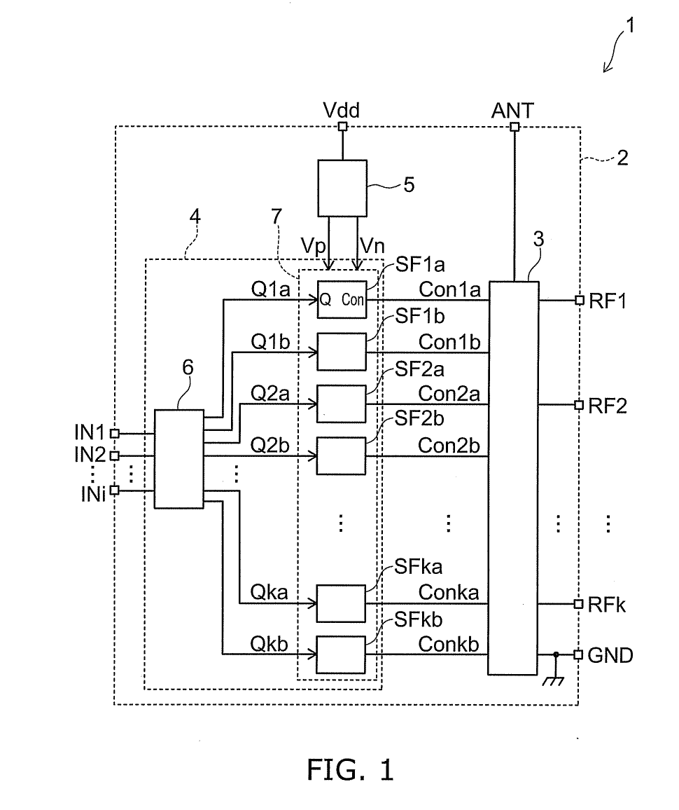

FIG. 1 is a block diagram illustrating a configuration of a semiconductor switch according to a first embodiment.

As illustrated in FIG. 1, a semiconductor switch 1 has a switch section 3 that switches connections between a common terminal ANT and radio frequency terminals RF1 to RFk (k is a natural number of two or more) including a first terminal RF1 and a second terminal RF2. The switch section 3 switches connections between the terminals according to control signals Con1a to Conka and Con1b to Conkb outputted from a controller 4.

The controller 4 switches between a normal operation mode and a test mode according to terminal switching signals inputted to switching signal terminals IN1 to INi. Here, a terminal number i of the switching signal terminals IN1 to INi is the number of bits that one bit indicating whether to be the normal operation mode or the test mode is added to the number of bits necessary to encode a radio frequency terminal to select, for example. The terminal number i of the switching signal terminals IN1 to INi is a minimum integer of two or more to satisfy i≧log₂k+1, for example.

In addition, the value of the aforementioned terminal number i is in the case where terminal switching signals inputted to the switching signal terminals IN1 to INi are parallel signals. In the case where serial signals are inputted to the switching signal terminals IN1 to INi, the terminal number i of the switching signal terminals IN1 to INi may be one.

In the case of the normal operation mode, the controller 4 connects the common terminal ANT to any one of the radio frequency terminals RF1 to RFk including the first terminal RF1 and the second terminal RF2 according to terminal switching signals. In the case of the test mode, the controller 4 connects the common terminal ANT to any two of the radio frequency terminals RF1 to RFk and to a ground terminal GND according to terminal switching signals. For example, the controller 4 connects the common terminal ANT to the first terminal RF1, the second terminal RF2, and the ground terminal GND.

A first potential Vp and a second potential Vn are supplied to the controller 4.

Here, the first potential Vp is a high-level potential of the control signals Con1a to Conka and Con1b to Conkb. The first potential Vp is a potential applied to the gate of each FET in the switch section 3 for turning on each FET, in which the ON resistance of the potential takes a sufficiently small value. For example, it is a potential of 3.5 V.

The second potential Vn is a low-level potential of the control signals Con1a to Conka and Con1b to Conkb. The second potential Vn is a potential that is applied to the gate of each FET in the switch section 3 for turning off each FET and that can sufficiently maintain the OFF state even though a radio frequency signal is superposed. For example, it is a potential of −1.5 V.

The first potential Vp and the second potential Vn are supplied from a power supply 5. The power supply 5 generates the first potential Vp higher than a positive power supply potential Vdd externally supplied and generates a negative second Vn. The power supply 5 is formed of an oscillator and a charge pump or the like, for example. The switch section 3, the controller 4, and the power supply 5 are all provided on a substrate 2, for example.

It is also possible to supply the power supply potential Vdd as the first potential Vp if the power supply potential Vdd supplied to the semiconductor switch 1 is a potential high enough to be applied to the gate of each FET in the switch section 3 for turning on each FET, in which the ON resistance of the potential takes a sufficiently small value. It is also possible to supply a ground potential as the second potential Vn if the ground potential is a potential that is applied to the gate of each FET in the switch section 3 for turning off each FET and that can sufficiently maintain the OFF state even though a radio frequency signal is superposed. In this case, the power supply 5 may be omitted.

In the case of the normal operation mode, the semiconductor switch 1 is a SPkT (Single-Pole k-Throw) switch to switch connections between the common terminal ANT and the radio frequency terminals RF1 to RFk according to terminal switching signals.

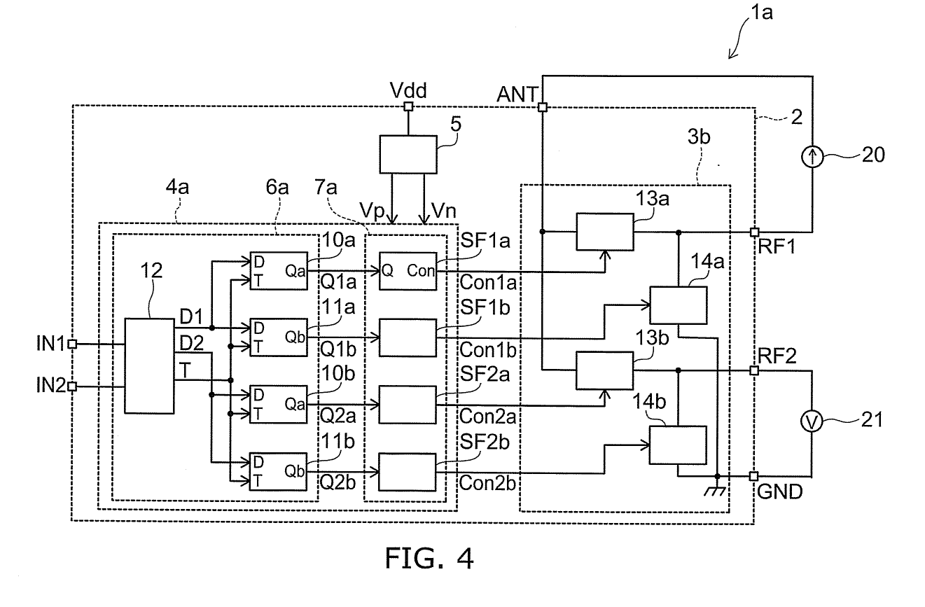

In the case of the test mode, the semiconductor switch 1 connects the common terminal ANT to any two of the radio frequency terminals RF1 to RFk and to the ground terminal GND according to terminal switching signals. As described in FIG. 4, in the case of the test mode, a DC resistance between the radio frequency terminals RF1 to RFk and the common terminal ANT can be measured.

Next, each of components will be described.

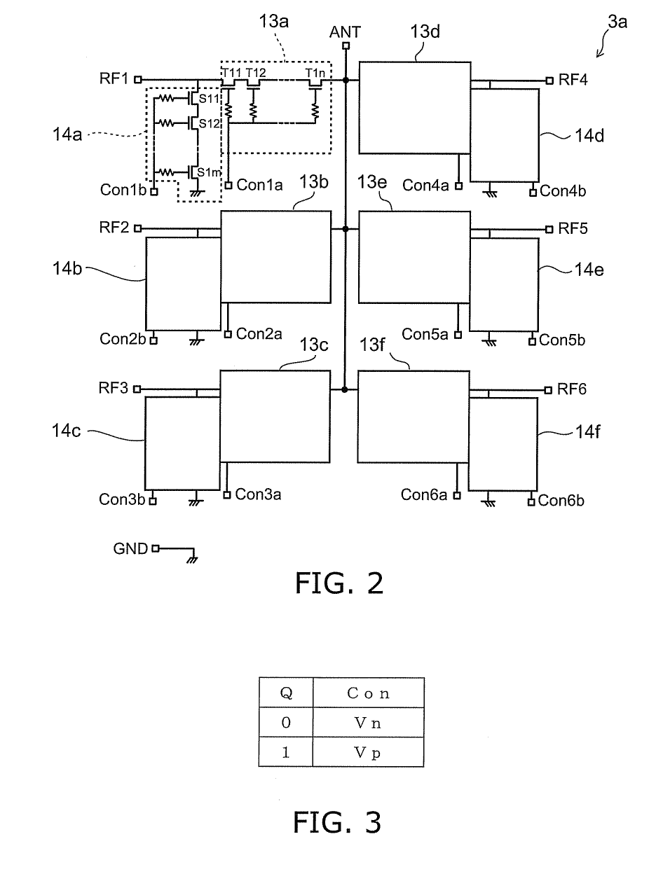

FIG. 2 is a circuit diagram illustrating a configuration of a switch section of the semiconductor switch shown in FIG. 1.

As illustrated in FIG. 2, in a switch section 3a, the configuration of the SP6T switch is illustrated. First switch elements 13a, 13b, 13c, 13d, 13e, and 13f are connected between the common terminal ANT and each of the radio frequency terminals RF1, RF2, RF3, RF4, RF5, and RF6 including the first terminal RF1 and the second terminal RF2, respectively. The first switch elements 13a to 13f are individually turned on, so that a transmission line is formed between the common terminal ANT and each of the radio frequency terminals RF1 to RF6.

In the first switch element 13a, through FETs T11, T12 to T1n in n stags (n is a natural number) are connected in series to each other. The control signal Con1a is inputted to the gates of the through FETs T11, T12 to Tin through a resister for preventing leakage of radio frequency. The first switch elements 13b to 13f have the same configuration as the configuration of the first switch element 13a. The control signals Con2a to Con6a are inputted to the first switch elements 13b to 13f, respectively.

A second switch element 14a is connected between the first terminal RF1 and the ground terminal GND. Third switch elements 14b to 14f are connected between the radio frequency terminals RF2 to RF6 except the first terminal RF1 and the ground terminal GND.

For example, in the case of the normal operation mode, the second switch element 14a and the third switch elements 14b to 14f are turned on when the first switch elements 13a to 13f are in the ON state. A leakage current flowing through each of the radio frequency terminals RF1 to RF6 is escaped to the ground terminal GND to improve isolation between the radio frequency terminals RF1 to RF6.

In the second switch element 14a, shunt FETs S11, S12 to S1m in m stages (m is a natural number) are connected in series to each other. The control signal Con1b is inputted to the gates of the shunt FETs S11, S12 to S1m through a resister for preventing leakage of radio frequency. The third switch elements 14b to 14f each have the same configuration as the configuration of the second switch element 14a. The control signals Con2b to Con6b are inputted to the third switch elements 14b to 14f, respectively.

For example, in the case of the normal operation mode, between the first terminal RF1 and the common terminal ANT conducts when the switch elements are controlled as below. The first switch element 13a between the first terminal RF1 and the common terminal ANT is turned on, and the second switch element 14a between the first terminal RF1 and the ground terminal GND is turned off. Namely, the through FETs T11, T12 to Tin in the first switch element 13a are all turned on, and the shunt FETs S11, S12 to S1m in the second switch element 14a are all turned off.

At the same time, the first switch elements 13b to 13f between the other radio frequency terminals RF2 to RF6 except the first terminal RF1 and the common terminal ANT are all turned off, and the third switch elements 14b to 14f between the other radio frequency terminals RF2 to RF6 except the first terminal RF1 and the ground terminal GND are all turned on. Namely, it is sufficient that the through FETs in the first switch elements 13b to 13f are all turned off and the shunt FETs in the third switch elements 14b to 14f are all turned on.

In the aforementioned case, the control signal Conga is set at the first potential Vp, the control signals Conga to Con6a at the second potential Vn, the control signal Con1b at the second potential Vn, and the control signals Con2b to Con6b at the first potential Vp.

In the case of the test mode, for example, the value of the DC ON resistance of the first switch element 13a between the first terminal RF1 and the common terminal ANT can be measured when the switch elements are controlled as below.

The first switch element 13a between the first terminal RF1 and the common terminal ANT is turned on, and the second switch element 14a between the first terminal RF1 and the ground terminal GND is turned on. Namely, the through FETs T11, T12 to Tin in the first switch element 13a are all turned on, and the shunt FETs S11, S12 to S1m in the second switch element 14a are all turned on.

At the same time, the first switch element 13b between the second terminal RF2 and the common terminal ANT is turned on, and the third switch element 14b between the second terminal RF2 and the ground terminal GND is turned off. Namely, it is sufficient that the through FETs in the first switch element 13b are all turned on and the shunt FETs in the third switch element 14b are all turned off.

The ground terminal GND is prevented from being connected to the common terminal ANT through the other radio frequency terminals RF3 to RF6. For example, at least any of the first switch element 13c to 13f between the other radio frequency terminals RF3 to RF6 and the common terminal ANT and the third switch element 14c to 14f between the other radio frequency terminals RF3 to RF6 and the ground terminal GND are all turned off. Namely, it is sufficient that at least any of the through FETs in the first switch element 13c to 13f and the shunt FETs in the third switch element 14c to 14f are all turned off.

In the aforementioned case, the control signal Con1a and the control signal Conga are set at the first potential Vp, the control signal Con1b at the first potential Vp, and the control signal Con2b at the second potential Vn. At least any of the control signals Con3a to Con6a and Con3b to Con6b is set at the second potential Vn, and the control signals that are not set at the second potential Vn are set at the first potential Vp. All the control signals Con3a to Con6a and Con3b to Con6b may be set at the second potential Vn.

In FIG. 2, although the SP6T switch is illustrated as the configuration of the switch section 3a, the switch section 3a can be similarly applied to switches in the other configurations, and the switch section 3a can also configure a wPkT switch (w is a natural number, and k is a natural number of two or more).

Again referring to FIG. 1, the controller 4 has a control signal generator 6 and a driver 7.

As described in FIG. 4, the control signal generator 6 generates control signals Q1a to Qka and Q1b to Qkb from terminal switching signals inputted to the switching signal terminals IN1 to INi. Here, the control signals Q1a to Qka and Q1b to Qkb are signals having the high-level potential of the signals at the power supply potential Vdd and the low-level potential of the signals at the ground potential.

The control signal generator 6 is switched between the normal operation mode and the test mode according to terminal switching signals.

In the normal operation mode, the control signal generator 6 generates the control signals Q1a to Qka and Q1b to Qkb to select the radio frequency terminals RF1 to RF6 to which the common terminal ANT is connected according to terminal switching signals. In the test mode, the control signal generator 6 generates the control signals Q1a to Qka and Q1b to Qkb to select the radio frequency terminals RF1 to RFk for which the ON resistance is measured according to terminal switching signals. It is possible to measure the value of an ON resistance between the selected radio frequency terminal and the common terminal.

In addition, it is sufficient that the terminal switching signal can select the normal operation mode and the test mode and can select the radio frequency terminals RF1 to RF6. As described above, it is may be unnecessary to add one bit indicating whether to be the normal operation mode or the test mode for encoding.

The driver 7 receives the control signals Q1a to Qka and Q1b to Qkb, and level-shifts the control signals Q1a to Qka and Q1b to Qkb to the control signals Con1a to Con6a and Con1b to Con6b having the high-level potential of the signals at the first potential Vp and the low-level potential of the signals at the second potential Vn. The driver 7 has 2k level shifters of level shifters SF1a to SFka and SF1b to SFkb in the same configuration, which are twice the number of the radio frequency terminals RF1 to RFk including the first terminal RF1 and the second terminal RF2 (k is a natural number of two or more).

The level shifters SF1a to SFka and SF1b to SFkb level-shift an input signal Q having the high-level potential of the signal at the power supply potential Vdd and the low-level potential of the signal at a potential of 0V to an output signal Con having the high-level potential of the signal at the first potential Vp and the low-level potential of the signal at the second potential Vn.

FIG. 3 is a truth table showing input-output characteristics of a level shifter of the semiconductor switch.

FIG. 3 shows the potential of the output signal Con with respect to the input signal Q of the level shifter SF1a.

The level shifters SF1a to SFka and SF1b to SFkb have the same configuration, and the other level shifters SF2a to SFka and SF1b to SFkb also have input-output characteristics similar to the input-output characteristics in FIG. 3.

It is noted that various types of circuitry configurations are possible for the circuitry configuration of the level shifters SF1a to SFka and SF1b to SFkb. The level shifters in the semiconductor switch 1 may have any circuitry configurations as long as circuitry configurations have the function to level-shift the high-level potential to the first potential Vp and the low-level potential to the second potential Vn.

In the case where the power supply potential Vdd is supplied as the first potential Vp and the ground potential is supplied as the second potential Vn as described above, the driver 7 may be omitted. In this case, the control signals Q1a to Qka and Q1b to Qkb are inputted to the switch section 3 as the control signals Con1a to Con6a and Con1b to Con6b.

Next, the configuration of the control signal generator 6 and the method for measuring an ON resistance between the terminals will be described more in detail as a SPDT (Single-Pole double-Throw) switch is taken as an example.

FIG. 4 is a block diagram illustrating a method for measuring an ON resistance including another configuration of a semiconductor switch. Components similar to those in FIG. 1 and FIG. 2 are marked with like reference numerals.

As illustrated in FIG. 4, a semiconductor switch is provided with a switch section 3b, a controller 4a, and a power supply 5. The switch section 3b is that the switch section 3a shown in FIG. 2 is formed to have a SPDT configuration. Namely, the switch section 3b has two radio frequency terminals RF1 and RF2 that are a first terminal RF1 and a second terminal RF2.

A first switch element 13a is connected between the first terminal RF1 and a common terminal ANT. A first switch element 13b is connected between the second terminal RF2 and the common terminal ANT. A second switch element 14a is connected between the first terminal RF1 and a ground terminal GND. A third switch element 14b is connected between the second terminal RF2 and the ground terminal GND.

FIG. 4 illustrates the configuration in which the ground terminal GND is grounded in the inside of the switch section 3b. The second switch element 14a and the third switch element 14b are connected to the ground terminal GND. However, it is also possible that the ground terminal GND is not grounded in the inside of the switch section 3b and the second switch element 14a and the third switch element 14b are connected to separate ground terminals.

The first switch elements 13a and 13b, the second switch element 14a, and the third switch element 14b are the same as those in FIG. 2.

The power supply 5 is the same as that in FIG. 1, and generates and supplies the first potential Vp and the second potential Vn to a driver 7a of the controller 4a.

The power supply 5 may supply the power supply potential Vdd as the first potential Vp if the power supply potential Vdd is a potential high enough to be applied to the gate of each FET in the switch section 3a for turning on each FET, in which the ON resistance of the potential takes a sufficiently small value. The power supply 5 may supply the ground potential as the second potential Vn if the ground potential is a potential that is applied to the gate of each FET in the switch section 3a for turning off each FET and that can sufficiently maintain the OFF state even though a radio frequency signal is superposed. In this case, the power supply 5 may be omitted.

The controller 4a generates control signals Con1a, Con1b, Con2a, and Con2b of four bits according to terminal switching signals of two bits inputted to switching signal terminals IN1 and IN2. The controller 4a has a control signal generator 6a and the driver 7a.

The driver 7a has level shifters SF1a, SF1b, SF2a, and SF2b of four bits. The level shifters SF1a, SF1b, SF2a, and SF2b are the same as the level shifters of the driver 7 shown in FIG. 1, and generate the control signals Con1a, Con2a, Con1b, and Con2b that control signals Q1a, Q2a, Q1b, and Q2b are level-shifted. In the case where the power supply potential Vdd is supplied as the first potential Vp and the ground potential is supplied as the second potential Vn, the driver 7a may be omitted.

In the control signal generator 6a, a decoder 12 decodes terminal switching signals of two bits inputted to the switching signal terminals IN1 and IN2, and outputs signals D1, D2, and T. Here, the signals D1 and D2 select the radio frequency terminals RF1 and RF2, respectively. For example, in the case of selecting the radio frequency terminal RF1, the signal D1 is made at high level, and the signal D2 is made at low level. The signal T indicates the normal operation mode or the test mode. For example, the signal T is made at low level in the normal operation mode, and at high level in the test mode.

First circuits 10a and 10b and second circuits 11a and 11b receive the signals D1, D2, and T, and generate the control signals Q1a, Q2a, Q1b, and Q2b. The first circuit 10a receives the signals D1 and T, and generates the control signal Q1a. The first circuit 10b receives the signals D2 and T, and generates the control signal Q2a. The second circuit 11a receives the signals D1 and T, and generates the control signal Q1b. The second circuit 11b receives the signals D2 and T, and generates the control signal Q2b.

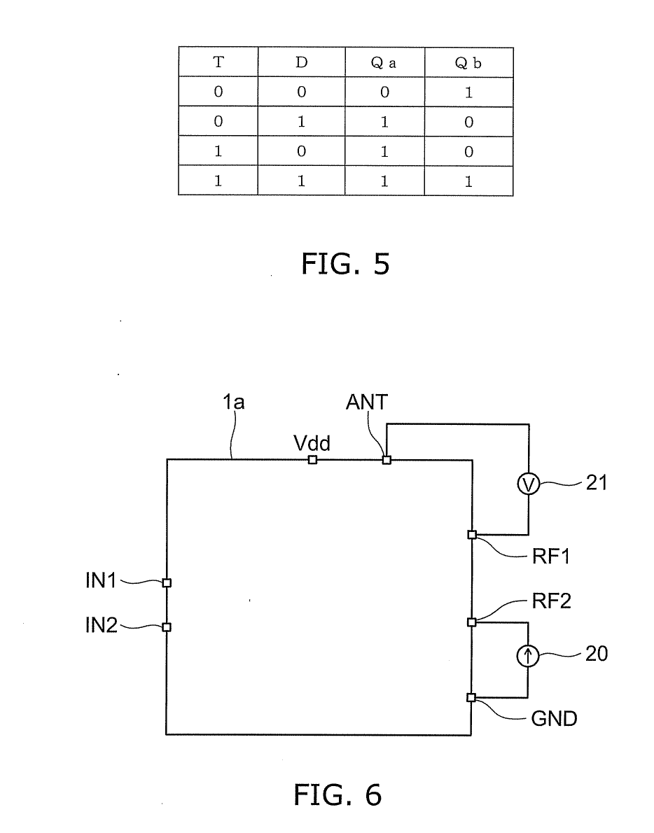

FIG. 5 is a truth table of first and second circuits of a controller.

The first circuits 10a and 10b have the same configuration; the first circuits 10a and 10b receive the signals D and T, and generate a signal Qa. The second circuits 11a and 11b have the same configuration; the second circuits 11a and 11b receive the signals D and T, and generate a signal Qb.

In FIG. 5, the first and second column show the signals T and D, respectively. The third column shows the signal Qa generated by the first circuits 10a and 10b, and the fourth column shows the signal Qb generated by the second circuits 11a and 11b.

In the normal operation mode, the signal T is at low level (0), the signal Qa is the same as the signal D, and the signal Qb takes the NOT of the signal D.

In the test mode, the signal T is at high level (1), the signal Qa is at high level (1), and the signal Qb is the same as the signal D.

From the truth table shown in FIG. 5, the first circuits 10a and 10b can be formed of an OR, and the second circuits 11a and 11b can be formed of an exclusive NOR (EXNOR), for example.

Again referring to FIG. 4, in the normal operation mode, the control signal generator 6a generates the control signals Q1a and Q2a as the signals having the same logic as the logic of the signals D1 and D2. The control signal generator 6a generates the control signals Q1b and Q2b as signals that negate the signals D1 and D2. The control signals Con1a, Con2a, Con1b, and Con2b are outputted from the controller 4a through the driver 7a.

For example, in the case where the decoder 12 outputs a high-level potential to the signal D1 and a low-level potential to the signal D2, the control signal Con1a is made at the first potential Vp at high level. The control signal Con2a is made at the second potential Vn at low level. The control signal Con1b is made at the second potential Vn at low level, and the control signal Con2b is made at the first potential Vp at high level.

The first switch element 13a is turned on, and the first switch element 13b is turned off. The second switch element 14a is turned off, and the third switch element 14b is turned on. The common terminal ANT is connected to the first terminal RF1.

For example, in the case where the decoder 12 outputs a high-level potential to the signal D1, a low-level potential to the signal D2, and a high-level potential to the signal T, the control signal Con1a is made at the first potential Vp at high level. The control signal Con2a is made at the first potential Vp at high level. The control signal Con1b is made at the first potential Vp at high level, and the control signal Con2b is made at the second potential Vn at low level.

Both of the first switch elements 13a and 13b are turned on.

The second switch element 14a is turned on, and the third switch element 14b is turned off. The common terminal ANT is connected to the first terminal RF1, the second terminal RF2, and the ground terminal GND.

### Second Embodiment

Next, a method for measuring a DC ON resistance between terminals of a semiconductor switch according to a second embodiment will be described with reference to FIG. 4.

A semiconductor switch is to be measured has first switch elements 13a and 13b connected between a plurality of radio frequency terminals RF1 and RF2 including a first terminal RF1 and a second terminal RF2 and a common terminal ANT, and a second switch element 14a connected between the first terminal RF1 and a ground terminal GND.

A third switch element 14b may be further included between the second terminal RF2 and the ground terminal GND as the semiconductor switch 1a according to the first embodiment. In the case where the third switch element 14b is connected between the other radio frequency terminal RF2 except the first terminal RF1 and the ground terminal GND, it is possible to measure the DC ON resistance of the first switch element 13b between the common terminal ANT and the other radio frequency terminal RF2 to which the third switch element 14b is connected.

First, as described above, terminal switching signals are inputted to switching signal terminals IN1 and IN2, and a decoder 12 outputs a high-level potential to a signal D1, a low-level potential to a signal D2, and a high-level potential to a signal T.

Namely, both of the first switch elements 13a and 13b connected to the first terminal RF1 and the second terminal RF2 are turned on. The second switch element 14a connected to the first terminal RF1 is turned on, and the third switch element 14b connected to the other second terminal RF2 is turned off. The common terminal ANT is connected to the first terminal RF1, the second terminal RF2, and the ground terminal GND.

A current flows through the first switch element 13a connected to the first terminal RF1. For example, as illustrated in FIG. 4, a current source 20 is connected between the first terminal RF1 and the common terminal ANT to force a current to flow through the first switch element 13a connected to the first terminal RF1.

Next, a voltage across the first switch element 13a connected to the first terminal RF1 is measured. For example, a voltmeter 21 is connected between the second terminal RF2 and the ground terminal GND to measure a voltage across the first switch element 13a connected to the first terminal RF1.

The measured value of the voltage across the first switch element 13a is divided by the value of the current flowing, so that it is possible to measure the DC ON resistance of the first switch element 13a connected to the first terminal RF1.

In the semiconductor switch 1a, the common terminal ANT is connected to the first terminal RF1, the second terminal RF2, and the ground terminal GND. Thus, it is possible to measure the DC ON resistance of the first switch element 13a highly accurately according to a four-terminal method.

In the case of a configuration where the common terminal ANT cannot be connected to the first terminal RF1, the second terminal RF2, and the ground terminal GND as the semiconductor switch 1a, it is also possible to measure a DC ON resistance as below, for example.

For example, when a DC ON resistance between the first terminal RF1 and the common terminal ANT is measured, forcing a DC current to flow between the first terminal RF1 and the common terminal ANT to measure a voltage across the first terminal RF1 and the common terminal ANT, so that it is possible to measure a resistance. For example, in the case where the aforementioned measurement is performed using a semiconductor chip, it is necessary to connect a sample to an external circuit such as a current source or voltmeter by contacting a probe with the terminal pad of the sample. However, in measurements like this, when a contact resistance between the contacting portions of the first terminal RF1 and the common terminal ANT is large, the contact resistance is increased up to about one ohm, for example.

In the case of the switch section 3a shown in FIG. 2, for the ON resistance between each of the radio frequency terminals RF1 to RF6 and the common terminal ANT, for example, the ON resistance of each through FET in the first switch elements 13a to 13f is predominant. The value of this ON resistance of the through FET is as small as about three ohms. Thus, it is difficult to highly accurately measure the value of the ON resistance between each of the radio frequency terminals RF1 to RF6 and the common terminal ANT.

On the contrary, in the semiconductor switches 1 and la, it is possible to turn on only the first switch elements 13a and 13b connected to the first terminal RF1 and to the second terminal RF2 and the second switch element 14a connected to the first terminal RF1.

Thus, in the case of measuring a voltage across the first switch element 13a connected to the first terminal RF1, it is possible that the voltmeter 21 is connected between the second terminal RF2 and the ground terminal GND, for example, to measure a voltage across the first switch element 13a connected to the first terminal RF1.

At this time, since the impedance of the voltmeter 21 is high enough as compared with the ON resistance of the first switch element 13a, a current does not flow through the voltmeter 21. Thus, it is possible to highly accurately measure a voltage across the first switch element 13a with no influence of the second terminal RF2 to which the voltmeter 21 is connected and the contact resistance between the ground terminal GND and the voltmeter 21.

The DC measurement is easier than the measurement of the radio frequency characteristics of the semiconductor switches 1 and 1a. A DC ON resistance between the common terminal ANT and each of the radio frequency terminals RF1 to RFk is measured, so that it is possible to confirm the operation of each FET in the switch sections 3, 3a, and 3b, and it is possible to measure the insertion loss of the direct current.

In FIG. 4, the current source 20 is connected between the first terminal RF1 and the common terminal ANT to force a current to flow through the first switch element 13a connected to the first terminal RF1. However, the other configurations are also possible.

FIG. 6 is a block diagram illustrating another method for measuring an ON resistance of a semiconductor switch. In FIG. 6, the internal structure of the semiconductor switch 1a is omitted in the drawing.

As illustrated in FIG. 6, the current source 20 is connected between the ground terminal GND and the second terminal RF2 of the semiconductor switch 1a to force a current to flow through the first switch element 13a connected to the first terminal RF1.

The voltmeter 21 is then connected between the first terminal RF1 and the common terminal ANT to measure a voltage across the first switch element 13a connected to the first terminal RF1.

The measured value of the voltage across the first switch element 13a is divided by the value of the current flowing, so that it is possible to measure the DC ON resistance of the first switch element 13a connected to the first terminal RF1.

Also in this case, since the impedance of the voltmeter 21 is high enough as compared with the ON resistance of the first switch element 13a, a current does not flow through the voltmeter 21. Thus, it is possible to highly accurately measure a voltage across the first switch element 13a with no influence of the first terminal RF1 to which the voltmeter 21 is connected and the contact resistance between the common terminal ANT and the voltmeter 21.

Although the semiconductor switch 1a is taken as an example and explained for the method for measuring an ON resistance, an ON resistance can be similarly measured using the semiconductor switch 1 shown in FIG. 1.

In the case of providing the third switch elements 14b to 14k connected between the radio frequency terminals RF1 to RFk except the first terminal RF1 and the ground terminal GND, it is possible to measure the DC ON resistance of each of the first switch element 13a to 13k connected to the radio frequency terminals RF1 to RFk according to terminal switching signals.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor switch comprising:
a plurality of first switch elements connected between a common terminal and each of a plurality of radio frequency terminals including a first terminal and a second terminal;
a second switch element connected between the first terminal and a ground terminal; and
a controller configured to output a control signal to turn on or off the plurality of first switch elements and the second switch element and perform a normal operation mode to connect the common terminal to any one of the plurality of radio frequency terminals and a test mode to connect the common terminal to the first terminal, the second terminal, and the ground terminal according to a terminal switching signal.

2. The switch according to claim 1,
wherein the controller turns on the second switch element in the test mode.

3. The switch according to claim 1, further comprising a third switch element connected between the second terminal and the ground terminal, the third switch element being turned on or off according to the control signal,
wherein the controller turns on any one of the second switch element and the third switch element according to the terminal switching signal in the test mode.

4. The switch according to claim 1, further comprising a third switch element connected between the ground terminal and each of the plurality of radio frequency terminals except the first terminal, the third switch element being turned on or off according to the control signal,
wherein the controller connects the common terminal to any two of the plurality of radio frequency terminals and to the ground terminal according to the terminal switching signal in the test mode.

5. The switch according to claim 4,
wherein the controller turns on any one of the second switch element and the third switch element in the test mode.

6. The switch according to claim 1, further comprising a power supply configured to generate a first potential higher than a positive power supply potential,
wherein the controller further has a driver configured to level-shift a high-level potential of the control signal to the first potential.

7. The switch according to claim 1,
wherein the controller is provided on a semiconductor substrate on which the first switch element and the second switch element are provided.

8. The switch according to claim 1,
wherein the controller performs any of the normal operation mode and the test mode according to the terminal switching signal.

9. The switch according to claim 1,
wherein the terminal switching signal is a parallel signal.

10. The switch according to claim 1,
wherein the terminal switching signal is a serial signal.

11. A method for measuring a DC ON resistance of one of a plurality of first switch elements connected to a first terminal of a semiconductor switch, the semiconductor switch having the plurality of first switch elements connected between a common terminal and a plurality of radio frequency terminals including the first terminal and a second terminal, and a second switch element connected between the first terminal and a ground terminal, the method comprising:
turning on one of the plurality of first switch elements connected to the first terminal and to the second terminal, and the second switch element connected to the first terminal;
forcing a current to flow through one of the plurality of first switch elements connected to the first terminal; and
measuring a voltage across one of the plurality of first switch elements connected to the first terminal.

12. The method according to claim 11,
wherein the turning on is inputting a terminal switching signal to a controller configured to output a control signal to turn on or off the plurality of first switch elements and the second switch element.

13. The method according to claim 11,
wherein the terminal switching signal is a parallel signal.

14. The method according to claim 11,
wherein the terminal switching signal is a serial signal.

15. The method according to claim 11, wherein:
the forcing the current to flow is forcing a current to flow between the common terminal and the first terminal; and
the measuring the voltage is measuring a voltage between the second terminal and the ground terminal.

16. The method according to claim 11, wherein:
the forcing the current to flow is forcing a current between the ground terminal and the second terminal; and
the measuring the voltage is measuring a voltage between the first terminal and the common terminal.

17. The method according to claim 11, wherein:
the semiconductor switch further has a third switch element connected between the second terminal and the ground terminal; and
the semiconductor switch turns off the third switch element.

18. The method according to claim 17,
wherein the turning on is inputting a terminal switching signal to a controller configured to output a control signal to turn on or off the plurality of first switch elements and the second switch element.

19. The method according to claim 17, wherein:
the forcing the current to flow is forcing a current to flow between the common terminal and the first terminal; and
the measuring the voltage is measuring a voltage between the second terminal and the ground terminal.

20. The method according to claim 17, wherein:
the forcing the current to flow is forcing a current to flow between the ground terminal and the second terminal; and
the measuring the voltage is measuring a voltage between the first terminal and the common terminal.
